(19) United States
(12) Patent Application Publication
(10) Pub. No.: US 2011/0206844 A1
(43) Pub. Date: Aug. 25, 2011

(54) CHROMIUM-FREE PASSIVATION OF VAPOR DEPOSITED ALUMINUM SURFACES

(76) Inventors: Jacob Grant Wiles, Fort Milll, SC (US); John R. Kochilla, Rock Hill, SC (US)

(21) Appl. No.: 12/711,431

(22) Filed: Feb. 24, 2010

(51) Int. Cl. B05D 3/00; C23C 16/28; C23C 14/34

(52) U.S. Cl. 427/250; 427/444; 204/192.15

(57) ABSTRACT

A process for passivating a vapor-deposited aluminum layer on a substrate, including providing a substrate comprising vapor deposited aluminum on a surface thereof; treating the surface of the substrate with an aqueous substantially chromium-free composition comprising a hexafluorozirconate; and rinsing the treated surface with water. A process for passivating a vapor-deposited aluminum layer on a substrate, including vapor depositing a layer of aluminum on a substrate; treating the substrate with the vapor deposited aluminum with an aqueous substantially chromium-free composition comprising a hexafluorozirconate; and rinsing the treated substrate with water.

### BACKGROUND

The present invention relates to passivation of vapor deposited aluminum surfaces applied to substrates such as ferrous metals, other metals and non-metals. More particularly, the present invention relates to vapor deposited aluminum on steel substrates.

Conventionally, chromium has been widely used to passivate substrates such as metal parts prior to application of subsequent layers such as electroplated metals or siccative organic coatings. However, even relatively safe passivates obtained from trivalent chromium can run afoul of regulations relating to (a) collection, re-use and recycling of waste electrical and electronic equipment (WEEE), (b) restriction of use of hazardous substances (RoHS) in electronic equipment, and/or (c) requirements for end of life vehicle (ELV) handling of automobiles, appliances and other equipment. Thus, using chromium as an example, even though trivalent chromium is safer than hexavalent chromium, both chromium sources result in the formation of articles containing chromium, which is a heavy metal and subject, inter alia, to the above-noted regulations.

Accordingly, it has long been desired to replace chromium-based passivates with less hazardous materials.

One such less hazardous material is aluminum. However, aluminum is itself a somewhat active metal and, while it can provide protection to underlying, more-active metals such as iron, it is itself subject to corrosion. Furthermore, a vapor deposited aluminum passivate layer is generally quite thin, so that even a small amount of corrosion of the aluminum may result in contact of the oxidized aluminum with the underlying substrate, thus thwarting the efforts to isolate and protect the substrate. As will be readily understood, if a layer applied to provide passivation is itself corroded, it may not function satisfactorily as a passivate as desired.

Accordingly, it has long been desired to provide improved passivates for vapor-deposited aluminum surfaces, but this long-sought goal has not yet been attained, despite numerous attempts.

### SUMMARY

The present invention provides a solution to the long-standing problem of provision of improved passivates for vapor-deposited aluminum surfaces.

Thus, in one embodiment, the present invention includes a process for passivating a vapor-deposited aluminum layer on a substrate, including:

providing a substrate comprising vapor deposited aluminum on a surface thereof;

treating the surface of the substrate with an aqueous substantially chromium-free composition comprising a hexafluorozirconate; and

rinsing the treated surface with water.

In another embodiment, the present invention includes a process for passivating a vapor-deposited aluminum layer on a substrate, including:

vapor depositing a layer of aluminum on a substrate;

treating the substrate with the vapor deposited aluminum with an aqueous substantially chromium-free composition comprising a hexafluorozirconate; and

rinsing the treated substrate with water.

In one embodiment, in either of the foregoing processes, the chromium-free composition comprising a hexafluorozirconate further comprises a magnesium salt, a nickel salt, a zinc salt or a combination of any two or more of the magnesium salt, the nickel salt and the zinc salt.

In one embodiment, in either of the foregoing processes, the vapor deposited aluminum is applied to the surface by decomposition of a metal-containing precursor having a decomposition temperature in a surrounding atmosphere, in which the substrate is maintained at a temperature greater than the decomposition temperature of the precursor while the surrounding atmosphere is maintained at a temperature lower than the decomposition temperature of the precursor.

In one embodiment, in either of the foregoing processes, the vapor deposited aluminum is applied to the surface by one or a combination of two or more of chemical vapor deposition, ion vapor deposition and physical vapor deposition.

In one embodiment, in either of the foregoing processes, the substrate comprises a ferrous metal on which the aluminum is vapor deposited. In one embodiment, the ferrous metal is steel.

In one embodiment, in either of the foregoing processes, the aqueous chromium-free composition is free of added zinc ions.

In one embodiment, in either of the foregoing processes, the aqueous chromium-free composition is free of added alkali metal ions.

In one embodiment, in either of the foregoing processes, the process further includes depositing at least one additional layer over the treated layer of aluminum, in which the additional layer includes one or more of a metal layer or an organic coating.

In one embodiment, in either of the foregoing processes, the hexafluorozirconate is provided as one or a mixture of any two or more of hexafluorozirconic acid, ammonium hexafluorozirconate, a quaternary ammonium hexafluorozirconate, an alkali metal hexafluorozirconate, an alkaline earth metal hexafluorozirconate, or a transition metal hexafluorozirconate.

Further details are provided in the following detailed description, in order to provide a written description of the invention, and of the manner and process of making and using it, in such terms as to enable any person skilled in the art to make and use the invention without undue experimentation, and sets forth the best mode for carrying out the invention as contemplated by the inventors.

### DETAILED DESCRIPTION

### Definitions

Throughout the disclosure and claims, the numerical limits of the ranges and ratios may be combined, and all ranges are deemed to include all subranges in unit increments.

Throughout the disclosure and claims, in listing alternatives, the disclosure is deemed to include all possible combinations of each listed alternative with each alternative in other lists, so that every combination of all possible alternatives is within the scope of the disclosure of the present invention. Furthermore, any individual member of a group of listed alternatives may be deleted from the list, and every subcombination resulting from such deletion is within the scope of the disclosure of the present invention.

### Substrates

Typical of the parts handled in accordance with the present invention are fasteners such as bolts, screws, nuts, fastening elements of other types like hinges, connectors, hook-type fasteners and the like, and all kinds of hardware, fixtures and fittings, including door, cabinet, kitchen, commercial, industrial and agricultural hardware and fittings.

In addition to the foregoing, prior to any of the process steps disclosed with respect to any of the embodiments, the substrates may be cleaned by various known methods. For example, substrates may be degreased, washed, dried, pickled, etc. Pickling may be carried out by any well-known pickling process, such as by using mineral inorganic acids, such as hydrochloric acid, sulfuric acid, nitric acid, and hydrofluoric acid, either individually or as mixtures.

### Vapor Deposition Processes

The process by which the aluminum layer is vapor deposited on the substrate may include any known vapor deposition method, including one or a combination of two or more of, for example, chemical vapor deposition (CVD), ion vapor deposition (IVD), and/or physical vapor deposition (PVD).

As known in the art, CVD processes include, for example, low pressure CVD (LPCVD), plasma-enhanced CVD (PECVD), plasma-assisted CVD (PACVD), remote plasma-enhanced (RPECVD), atomic layer CVD (ALCVD), hot wire CVD (HWCVD—also known as catalytic CVD (Cat-CVD) or hot filament CVD (HFCVD)), metalorganic chemical vapor deposition (MOCVD), hybrid physical-chemical vapor deposition (HPCVD), rapid thermal CVD (RTCVD), vapor phase epitaxy (VPE), and electron cyclotron resonance chemical vapor deposition (ECR•CVD).

IVD processes are well known in the art and may be carried out in vacuum at about 6×10⁻³ Torr. A high negative potential is applied to the metallic surfaces to be coated. Positively charged argon ions continuously bombard these surfaces to remove contaminants and water vapor. The metal (e.g., aluminum) is vaporized and attracted by the negative charge on the metallic substrate. In one embodiment, (direct) ion beam deposition (IBD) is used for the vapor deposition of aluminum.

As known in the art, PVD processes include, for example, evaporative deposition, electron beam physical vapor deposition, sputter deposition, direct current arc deposition, cathodic arc deposition, filtered cathodic arc (FCA) deposition, pulsed laser deposition, laser ablation and DC/RF planar magnetron sputtering.

Addition information on some vapor deposition methods can be found in, e.g., ASM Handbook, Surface Engineering, Vol. 5, “Vacuum Deposition, Reactive Evaporation, and Gas Evaporation”, ASM International (1999), pages 556-571.

Any known method of CVD, IVD and/or PVD may be used in accordance with the present invention for vapor depositing the layer of aluminum on the substrate. Furthermore, any of these methods may be combined, e.g., sequentially, with any other of these methods within the scope of the present invention.

In one embodiment, the vapor deposition method is a MOCVD process, such as that disclosed in U.S. Pat. No. 7,387,815 B2 (“U.S. Pat. No. 7,387,815”), the disclosure of which can be consulted for additional details and is incorporated herein by reference. The process disclosed in U.S. Pat. No. 7,387,815 deposits a substantially pure, conformal metal layer on a substrate through the decomposition of a metal-containing precursor. During this deposition process, the substrate is maintained at a temperature greater than the decomposition temperature of the precursor while the surrounding atmosphere is maintained at a temperature lower than the decomposition temperature of the precursor. The precursor is dispersed within a transport medium, e.g., a vapor phase. The precursor may be, for example, a metal alkyl compound. For aluminum, the disclosed precursors include a liquid metal alkyl compound, such as trimethylaluminum, dimethylaluminum hydride, triethylaluminum, diethylaluminum hydride, triisobutylaluminum, diisobutylaluminum hydride, or other trialkylaluminum or dialkylaluminum hydride molecule of the formula R¹R²R³Al, where R¹, R², and R³ are branched, straight chain, or cyclic hydrocarbyl ligands or hydrogen, and where the number of carbon atoms in R¹, R², and R³ range from C₁ to about C₁₂. The chosen ligands may also include those such as butadienyl or isoprenyl which are bifunctional and which bond to two or three aluminum atoms. The selected liquid/vapor precursor compositions may contain mixtures of any or all of the above-mentioned species.

U.S. Pat. No. 7,387,815 states that, preferably, R¹, R², and R³ as described above are selected from ethyl, isobutyl, and hydrogen, with the most preferred compounds being triisobutylaluminum, diisobutylaluminum hydride or mixtures of the two.

U.S. Pat. No. 7,387,815 discloses that the transport medium may also contain a dilute solution of the metal alkyl in a variety of non-reactive solvents with a range of boiling points from about 60° C. to over about 200° C. and at aluminum alkyl concentrations ranging from about 5 to about 95 wt %.

U.S. Pat. No. 7,387,815 further discloses that various methods may be used for heating the substrate to the desired temperature, including an indirect “non-contact” heating method in which the heating of the substrate is induced by electromagnetic induction or irradiation with microwave, UV, or IR energy. In an alternative embodiment, an induction heating method, such as electromagnetic induction, by inducing electrical current within the substrate to produce heat.

In one embodiment, the aluminum is provided to the vapor deposition process as dimethylethylamine alane, [(CH₃)₂(CH₃CH₂)N]AlH₃, as disclosed in U.S. Pat. No. 5,191,099, the disclosure of which can be consulted for additional details and is incorporated herein by reference.

In another embodiment, the aluminum is provided to the vapor deposition process as an amido/amine alane complex, H₂Al[(R¹)(R²)NC₂H₄NR³], in which R¹, R² and R³ are each independently H or C₁-C₃ alkyl, as disclosed in U.S. Pat. No. 5,880,303, the disclosure of which can be consulted for additional details and which is incorporated herein by reference.

In other embodiments, the aluminum is provided to the vapor deposition process as an organometallic compound such as those disclosed in U.S. Pat. No. 6,121,443, U.S. Pat. No. 6,143,357 or U.S. Pat. No. 6,500,250, the disclosure of each of which can be consulted for additional details and which are incorporated herein by reference.

### Passivation of the Deposited Aluminum on the Substrate

The process of passivating the vapor-deposited aluminum layer on the substrate includes treating the layer and substrate with an aqueous, substantially chromium-free composition containing either a salt of hexafluorozirconate or a salt of hexafluorozirconate together with (a) a magnesium salt, (b) a nickel salt, or (c) a zinc salt or (d) a combination of any two or more of the magnesium, nickel and zinc salts. The aqueous composition may be applied to the substrate by any appropriate method, including, for example, spraying, dipping, immersing, barrel treatment in bulk, brushing, wiping or any other suitable process for applying an aqueous liquid to a solid substrate. Where the vapor-deposited aluminum has been applied in a bulk processing step, such as in a barrel or other bulk apparatus, in one embodiment, the following step of the process according to the invention, i.e., the treating with the aqueous composition, also may be carried out in the same barrel or bulk apparatus.

The hexafluorozirconate can be provided in either the acid form (H₂ZrF₆) or as a salt, in which the cation portion of the hexafluorozirconate salt may be, for example, one or more of ammonium ion, a quaternary ammonium ion, an alkali metal ion, an alkaline earth metal ion or a transition metal ion. Thus, the hexafluorozirconate may be provided to the aqueous, substantially chromium-free composition in the form of one or a mixture of any two or more of hexafluorozirconic acid, ammonium hexafluorozirconate, a quaternary ammonium hexafluorozirconate, an alkali metal hexafluorozirconate, an alkaline earth metal hexafluorozirconate, or a transition metal hexafluorozirconate. For convenience, herein the hexafluorozirconate is referred to simply as hexafluorozirconate, and this is deemed to include the acid form as well as any of the salt forms, unless otherwise specifically identified as the acid form or as one or more specific salt form. In one embodiment, the quaternary ammonium ion comprises independently four C₁-C₄ alkyl groups.

In one embodiment, the aqueous, substantially chromium-free composition containing hexafluorozirconate contains from about 0.001 mole per liter (M) to about 0.25 M of the hexafluorozirconate. In another embodiment, the aqueous composition contains from about 0.004 M to about 0.1 M of the hexafluorozirconate. In another embodiment, the aqueous composition contains from about 0.008 M to about 0.05 M of the hexafluorozirconate. In another embodiment, the aqueous composition contains from about 0.008 M to about 0.012 M of the hexafluorozirconate. In another embodiment, the aqueous composition contains about 0.02 M, and in one embodiment, about 0.0196 M, of the hexafluorozirconate.

In one embodiment, when the aqueous, substantially chromium-free composition contains a salt of hexafluorozirconate together with (a) a magnesium salt, the composition contains the magnesium salt at a concentration in the range from about 0.01 mole per liter (M) to about 1 M. In another embodiment, the composition contains the magnesium salt at a concentration in the range from about 0.03 mole per liter (M) to about 0.2 M. In another embodiment, the composition contains the magnesium salt at a concentration in the range from about 0.05 mole per liter (M) to about 0.1 M. In another embodiment, the composition contains the magnesium salt at a concentration in the range from about 0.06 mole per liter (M) to about 0.08 M. In another embodiment, the composition contains the magnesium salt at a concentration of about 0.072 mole per liter (M).

The magnesium salt may be provided with any suitable counterion, and in one embodiment, is provided as magnesium nitrate. Other suitable counterions include, for example, sulfate, phosphate, sulfonate, phosphonate, carbonate, etc.

In one embodiment, when the aqueous, substantially chromium-free composition contains a salt of hexafluorozirconate together with (b) a nickel salt, the composition contains the nickel salt at a concentration in the range from about 0.008 mole per liter (M) to about 1 M. In another embodiment, the composition contains the nickel salt at a concentration in the range from about 0.01 mole per liter (M) to about 0.2 M. In another embodiment, the composition contains the nickel salt at a concentration in the range from about 0.025 mole per liter (M) to about 0.1 M. In another embodiment, the composition contains the nickel salt at a concentration in the range from about 0.03 mole per liter (M) to about 0.05 M. In another embodiment, the composition contains the nickel salt at a concentration of about 0.032 mole per liter (M).

The nickel salt may be provided with any suitable counterion, and in one embodiment, is provided as nickel sulfate. Other suitable counterions include, for example, nitrate, phosphate, sulfonate, phosphonate, carbonate, etc.

In one embodiment, when the aqueous, substantially chromium-free composition contains a salt of hexafluorozirconate together with (c) a zinc salt, the composition contains the zinc salt at a concentration in the range from about 0.001 mole per liter (M) to about 1 M. In another embodiment, the composition contains the zinc salt at a concentration in the range from about 0.01 mole per liter (M) to about 0.2 M. In another embodiment, the composition contains the zinc salt at a concentration in the range from about 0.02 mole per liter (M) to about 0.1 M. In another embodiment, the composition contains the zinc salt at a concentration in the range from about 0.03 mole per liter (M) to about 0.05 M. In another embodiment, the composition contains the zinc salt at a concentration of about 0.04 mole per liter (M). The zinc salt is normally provided as a divalent zinc salt.

The zinc salt may be provided with any suitable counterion, and in one embodiment, is provided as zinc sulfate. Other suitable counterions include, for example, acetate, phosphate, sulfonate, phosphonate, carbonate, etc.

In one embodiment in which the aqueous, substantially chromium-free composition contains a salt of hexafluorozirconate together with (d) a combination of magnesium, nickel and/or zinc salts, the composition contains the magnesium salt, the nickel salt and/or the zinc salt within the foregoing ranges. In one embodiment, in which the aqueous, substantially chromium-free composition contains a salt of hexafluorozirconate together with a combination of magnesium and nickel salts, the composition contains a ratio of magnesium to nickel in the range from about 1:20 to about 20:1, or at any ratio within this range. In one embodiment, in which the aqueous, substantially chromium-free composition contains a salt of hexafluorozirconate together with a combination of magnesium and zinc salts, the composition contains a ratio of magnesium to zinc in the range from about 1:20 to about 20:1, or at any ratio within this range. In one embodiment, in which the aqueous, substantially chromium-free composition contains a salt of hexafluorozirconate together with a combination of zinc and nickel salts, the composition contains a ratio of zinc to nickel in the range from about 1:20 to about 20:1, or at any ratio within this range. In an embodiment in which the aqueous, substantially chromium-free composition contains a salt of hexafluorozirconate together with a combination of magnesium, nickel and zinc salts, the composition contains ratios of magnesium to nickel to zinc within the foregoing ranges.

When the aqueous, substantially chromium-free composition contains a salt of hexafluorozirconate together with a combination of magnesium, nickel and/or zinc salts, the hexafluorozirconate may be provided with any one of the magnesium, nickel or zinc as its counterion.

The foregoing concentrations of each of the hexafluorozirconate, the magnesium, the nickel and the zinc may be suitably selected independently and combined within the foregoing ranges. That is, each of the possible combinations of concentrations of hexafluorozirconate, magnesium salt, nickel salt and/or zinc salt are deemed to fall within the scope of the foregoing disclosure, even though each possible combination is not slavishly recited. Thus, for example, the hexafluorozirconate may be at or near the upper end of the foregoing ranges in combination with any one or more of the magnesium, nickel and zinc ions, which may be at comparable or lower concentrations. Similarly, the hexafluorozirconate may be at or near the lower end of the foregoing ranges in combination with any one or more of the magnesium, nickel and zinc ions, which may be at comparable or higher concentrations. Persons skilled in the art will readily recognize, understand and derive that all of these possible combinations are within the scope of the present disclosure.

In one embodiment, the aqueous, substantially chromium-free composition containing either a salt of hexafluorozirconate or a salt of hexafluorozirconate together with (a) a magnesium salt, (b) a nickel salt, (c) a zinc salt or (d) a combination of any two or more of the magnesium, nickel and zinc salts, is substantially free of other added ingredients, except for pH adjusting acid or base. Thus, in one embodiment, the aqueous, substantially chromium-free composition containing either a salt of hexafluorozirconate or a salt of hexafluorozirconate together with (a) a magnesium salt, (b) a nickel salt, (c) a zinc salt or (d) a combination of any two or more of the magnesium, nickel and zinc salts contains no additives such as added surfactants, other added metal ions (except as noted, for pH adjustment), added salts or buffers. Thus, in various embodiments, the aqueous, substantially chromium-free composition consists essentially of the hexafluorozirconate, consists essentially of the hexafluorozirconate and a magnesium salt, consists essentially of the hexafluorozirconate and a nickel salt or consists essentially of the hexafluorozirconate and a zinc salt, or consists essentially of the hexafluorozirconate and a combination of any two or more of a magnesium salt, a nickel salts and a zinc salt.

The aqueous, substantially chromium-free composition containing either a salt of hexafluorozirconate or a salt of hexafluorozirconate together with (a) a magnesium salt, (b) a nickel salt, (c) a zinc salt or (d) a combination of any two or more of magnesium, nickel and zinc salts is agitated or stirred during its application to the vapor-deposited aluminum substrate to help maintain uniformity of the concentrations of ingredients and thereby to maintain uniformity of the applied treatment.

In one embodiment, the aqueous, substantially chromium-free composition containing either a salt of hexafluorozirconate or a salt of hexafluorozirconate together with (a) a magnesium salt, (b) a nickel salt, (c) a zinc salt or (d) a combination of any two or more of magnesium, nickel and zinc salts is maintained at a pH in the range from about 2.5 to about 6, and in another embodiment, this composition is maintained at a pH in the range from about 3 to about 5, and in another embodiment, this composition is maintained at a pH of about 4 to about 4.5.

In one embodiment, the aqueous, substantially chromium-free composition containing either a salt of hexafluorozirconate or a salt of hexafluorozirconate together with (a) a magnesium salt, (b) a nickel salt, (c) a zinc salt or (d) a combination of any two or more of magnesium, nickel and zinc salts is applied at a temperature ranging from about 20° C. to about 160° C., and in another embodiment, this composition is applied at a temperature ranging from about 40° C. to about 70° C.

In one embodiment, the aqueous, substantially chromium-free composition containing either a salt of hexafluorozirconate or a salt of hexafluorozirconate together with (a) a magnesium salt, (b) a nickel salt, (c) a zinc salt or (d) a combination of any two or more of magnesium, nickel and zinc salts is applied for a time ranging from about 1 minute to about 10 minutes, and in another embodiment, this composition is applied for a time ranging from about 2 minutes to about 6 minutes, and in another embodiment, this composition is applied for a time of about 4 minutes.

In one embodiment, in any of the processes described herein in accordance with the present invention, the process may further include depositing at least one additional layer over the treated layer of aluminum, in which the additional layer includes one or more of a metal layer or an organic coating. The additional metal layer(s) may be deposited by any one or more of electrodeposition, electroless plating or immersion plating, by any suitable one of these methods known in the art. The additional organic coating(s) may be any known coating for metal items, such as a siccative organic coating, a paint, a lubricant, a sealant, an anti-corrosive material, or any other suitable organic coating known in the art. Such organic coatings may be applied by any method known in the art, such as spraying, brushing, dipping, etc.

### EXAMPLES

The following experiment shows that an aqueous, substantially chromium-free composition containing either a salt of hexafluorozirconate or a salt of hexafluorozirconate together with (a) a magnesium salt, (b) a nickel salt, (c) a zinc salt or (d) a combination of any two or more of magnesium, nickel and zinc salts in accordance with the present invention is superior to conventional Cr⁺³ passivates on vapor deposited aluminum coatings on substrates. Vapor-deposited aluminized fasteners were obtained from Akzo Nobel using their current FUZEBOX® technology (which, on information and belief, is described in U.S. Pat. No. 7,387,815 B2). This experiment uses electrochemical corrosion techniques to obtain a quick and accurate comparison of corrosion rates, when the processes are applied to treat both vapor-deposited aluminized fasteners and a solid strip of alloy 1100 aluminum. As shown by the following, there is a difference in corrosion protection between vapor deposited aluminum on a substrate of a different metal and a substrate formed of a solid aluminum alloy.

### Example 1

Two sets of sample substrates are prepared for these tests. A first set of fasteners with the FUZEBOX® vapor-deposited aluminum are tested together with a second set of strips of 1100 series aluminum alloy. The 1100 aluminum alloy is 99% aluminum, which is the highest aluminum content of all aluminum alloys and is thus, for comparative purposes, closest in composition to the FUZEBOX® vapor-deposited aluminum, which is considered to be substantially pure (e.g., at least 99.9%) aluminum.

Set 1=FUZEBOX® Coated Fasteners

Set 2=1100 Aluminum (1″×3″ strips)

Process Cycle (Both Sets)

1. ALKALUME® 143 (50 g/l, 60° C., 5 min)

### 2. Rinse

3. Alklean AC-2™ (10%, 20° C., 2 min)

### 4. Water Rinse

5. Desmutter NF-2™ (80 g/l, 20° C., 1 min)

### 6. Water Rinse

7. Pretreatment Solutions (25° C., 5 min)

### 8. Deionized Water Rinse

9. Oven Dry (100° C., 10 min)
ALKALUME® is a proprietary composition for use in cleaning magnesium and aluminum substrates; Alklean AC-2™ is a proprietary composition for use in cleaning metal substrates; Desmutter NF-2™ is a proprietary composition for use in desmutting metal substrates; all three are available from Atotech USA, Rock Hill, S.C.

### Compositions Applied to Vapor Deposited Aluminum and Aluminum Strips

1. No treatment, clean aluminum surface only, as described above.

### 2. INTERLOX® 338

| | |
|---|---|
| (NH₄)₂ZrF₆ | 5 g/l (~1.9 g/l Zr) |
| Chromium chloride (CrCl₃•6H₂O) | 7 g/l (~1.37 g/l Cr) |

3. Present Invention, hexafluorozirconate and Mg ions

| | |
|---|---|
| (NH₄)₂ZrF₆ | 5.0 g/l (~1.9 g/l Zr) |
| Mg(NO₃)₂•6 H₂O | 6.3 g/l (~0.75 g/l Mg) |

4. Present Invention, hexafluorozirconate and Zn ions

| | |
|---|---|
| (NH₄)₂ZrF₆ | 5.0 g/l (~1.9 g/l Zr) |
| ZnSO₄•7 H₂O | 9.18 g/l (~2.1 g/l Zn) |

5. Present invention, hexafluorozirconate and Ni ions

| | |
|---|---|
| (NH₄)₂ZrF₆ | 5.0 g/l (~1.9 g/l Zr) |
| NiSO₄•6 H₂O | 8.43 g/l (~1.9 g/l Ni) |

After panels and fasteners are treated in the above solution, they are evaluated using a PARSTAT 2273 potentiostat instrument with the PowerCORR software from Princeton Applied Research. Below are the conditions under which the corrosion tests are carried out:

Cell Definition
Electrolyte solution: 5% NaCl (fresh solution for each specimen)
Working Electrode area: 1.000 cm²
Density (Al)=2.7000 g/ml
Equivalent Weight (Al)=9.000 grams
Reference Electrode: Ag, AgCl/KCl (sat'd) (0.197 V)

Scan Definition
Initial Potential: −0.250 V vs open circuit
Final Potential: 0.250 V vs open circuit
Step Height: 0.5000 mV
Scan Rate: 2.00 mV/s
Step Time: 0.250 s
Number of Points: 1001

Corrosion Calculations

$$Corrosion Rate ( m p y ) = \frac{0.13 {I}_{corr} ( E . W . )}{A * d}$$

where mpy=milliinches per year
I_{corr}=corrosion current
*=factor determined by tafel constants given for each test
A=area (cm²)
d=density (g/cm³)
0.13=Metric and time conversion factor
   The results are shown in the following table:

| | E (I = 0) | Icorr | CR (mpy) | % Corrosion |
|---|---|---|---|---|
| FUZEBOX Fasteners | | | | |
| Clean Only | −370.371 | 338.2 | 145.1 | 100.00% |
| INTERLOX ® 338 | −447.39 | 41.6 | 17.85 | 12.30% |
| Hexafluorozirconate | −505.085 | 18.04 | 7.739 | 5.33% |
| w/ Mg | | | | |
| Hexafluorozirconate | −733.414 | 47.05 | 8.4 | 5.79% |
| w/ Zn | | | | |
| Hexafluorozirconate | −346.447 | 11.06 | 1.974 | 1.36% |
| w/ Ni | | | | |
| 1100 Al Alloy | | | | |
| Clean Only | −399.806 | 4.525 | 1.941 | 100.00% |
| INTERLOX ® 338 | −602.395 | 0.5737 | 0.2461 | 12.68% |
| Hexafluorozirconate | −323.839 | 0.7101 | 0.3046 | 15.69% |
| w/ Mg | | | | |
| Hexafluorozirconate | −724.435 | 34.17 | 14.66 | 755.28% |
| w/ Zn | | | | |
| Hexafluorozirconate | −259.742 | 12.4 | 5.318 | 273.98% |
| w/ Ni | | | | |

As shown by the foregoing example, on vapor-deposited aluminum surfaces, the hexafluorozirconate in accordance with embodiments of the present invention provides superior corrosion protection as compared to “clean only” and the trivalent chromium passivates such as INTERLOX® 338, and provides comparable corrosion protection compared to the process disclosed in US 2007/0099022.

### Example 2

A second set of fasteners with the FUZEBOX® vapor-deposited aluminum are tested in this example, using six different treatments and no treatment. In this example the test substrates are #6 FUZEBOX® vapor-deposited aluminum-coated fasteners obtained from Akzo Nobel.

Process Sequence

1. ALKALUME® 143 (50 g/l, 60° C., 5 min)

### 2. Rinse

3. Alklean AC-2™ (10%, 20° C., 2 min)

### 4. Rinse

5. Desmutter NF-2™ (80 g/l, 20° C., 1 min)

### 6. Rinse

7. Pretreatment Solutions (48° C., 5 min)

### 8. DI Rinse

9. Oven Dry (100° C., 10-15 min)

### Compositions Applied to Vapor Deposited Aluminum Fasteners

1. No treatment, clean vapor deposited aluminum surface only, as described above.
2. Present Invention, hexafluorozirconate only

| | |
|---|---|
| (NH₄)ZrF₆ | 5.16 g/l |

3. Present Invention, hexafluorozirconate and magnesium

| | |
|---|---|
| (NH₄)ZrF₆ | 5.16 g/l |
| Mg(NO₃)₂•6 H₂O | 6.285 g/l |

4. Present Invention, hexafluorozirconate and nickel

| | |
|---|---|
| (NH₄)ZrF₆ | 5.16 g/l |
| NiSO₄•6 H₂O | 8.43 g/l |

5. Present Invention, hexafluorozirconate and zinc

| | |
|---|---|
| (NH₄)ZrF₆ | 5.16 g/l |
| ZnSO₄•7 H₂O | 9.18 g/l |

6. Present Invention, hexafluorozirconate, magnesium and nickel

| | |
|---|---|
| (NH₄)ZrF₆ | 5.16 g/l |
| Mg(NO₃)₂•6 H₂O | 6.285 g/l |
| NiSO₄•6 H₂O | 8.43 g/l |

7. Present Invention, hexafluorozirconate, magnesium and zinc

| | |
|---|---|
| (NH₄)ZrF₆ | 5.16 g/l |
| Mg(NO₃)₂•6 H₂O | 6.285 g/l |
| ZnSO₄•7 H₂O | 9.18 g/l |

After panels and fasteners are treated in the above solution, they are evaluated using a PARSTAT 2273 potentiostat instrument with the PowerCORR software from Princeton Applied Research. Below are the conditions under which the corrosion tests are carried out:

Instrument Parameters

### Cell Definition

Electrolyte solution: 5% NaCl (fresh solution for each specimen)
Working Electrode area: ˜1.50 cm2
Density: Al=2.7000 g/ml
   Zr=6.52 g/ml
Equivalent Weight: Al=9.00 grams
   Zr=22.8 grams
Reference Electrode: Ag, AgCl/KCl (sat'd) (0.197 V)

### Scan Definition

Initial Potential: −0.250 V vs open circuit
Final Potential: 0.250 V vs open circuit
Step Height: 0.5000 mV
Scan Rate: 2.00 mV/s
Step Time: 0.250 s
Number of Points: 1001

Corrosion Calculations

$$Corrosion Rate ( m p y ) = \frac{0.13 {I}_{corr} ( E . W . )}{A * d}$$

where mpy=milliinches per year
I_{corr}=corrosion current
   *determined by tafel constants given for each test
A=area (cm²)
d=density (g/cm³)
0.13=Metric and time conversion factor

Results

The corrosion test results of the samples in Example 2 are shown in the following table:

| | | E (I = 0) | Icorr | | |
|---|---|---|---|---|---|
| Solution | Treatment | (mV) | (μA) | CR (mpy) | % Corrosion |
| 1 | Clean Only | −610.554 | 352.9 | 50.46 | 100.00 |
| 2 | Zr Only | −738.064 | 1.922 | 0.579 | 1.15 |
| 3 | Zr & Mg | −328.991 | 5.514 | 1.662 | 3.29 |
| 4 | Zr & Ni | −371.678 | 3.325 | 1.002 | 1.99 |
| 5 | Zr & Zn | −335.675 | 6.786 | 2.014 | 3.99 |
| 6 | Zr, Mg and Ni | −642.656 | 9.640 | 2.303 | 4.56 |
| 7 | Zr, Mg and Zn | −605.324 | 6.549 | 1.974 | 3.91 |

As shown by the foregoing example, on vapor-deposited aluminum surfaces, the hexafluorozirconate in accordance with embodiments of the present invention provides superior corrosion protection as compared to “clean only”. By comparison with the results in Example 1, the results in Example 2 show that the present invention both performs substantially better than the trivalent chromium passivate exemplified by INTERLOX® 338, and performs substantially better than the process disclosed in US 2007/0099022.

It is noted that, throughout the specification and claims, the numerical limits of the disclosed ranges and ratios may be combined, and are deemed to include all intervening values. Furthermore, all numerical values are deemed to be preceded by the modifier “about”, whether or not this term is specifically stated.

While the principles of the invention have been explained in relation to certain particular embodiments, and are provided for purposes of illustration, it is to be understood that various modifications thereof will become apparent to those skilled in the art upon reading the specification. Therefore, it is to be understood that the invention disclosed herein is intended to cover such modifications as fall within the scope of the appended claims. The scope of the invention is limited only by the scope of the claims.

1. A process for passivating a vapor-deposited aluminum layer on a substrate, comprising:
providing a substrate comprising vapor deposited aluminum on a surface thereof;
treating the surface of the substrate with an aqueous substantially chromium-free composition comprising a hexafluorozirconate; and
rinsing the treated surface with water.

2. The process of claim 1 wherein the chromium-free composition comprising a hexafluorozirconate further comprises a magnesium salt, a nickel salt, a zinc salt or a combination of any two or more of a magnesium salt, a nickel salt and a zinc salt.

3. The process of claim 1 wherein the vapor deposited aluminum is applied to the surface by decomposition of a metal-containing precursor having a decomposition temperature in a surrounding atmosphere, in which the substrate is maintained at a temperature greater than the decomposition temperature of the precursor while the surrounding atmosphere is maintained at a temperature lower than the decomposition temperature of the precursor.

4. The process of claim 1 wherein the vapor deposited aluminum is applied to the surface by one or a combination of two or more of chemical vapor deposition, ion vapor deposition and physical vapor deposition.

5. The process of claim 1 wherein the substrate comprises a ferrous metal on which the aluminum is vapor deposited.

6. The process of claim 5 wherein the ferrous metal is steel.

7. The process of claim 1 wherein the aqueous chromium-free composition is free of added zinc ions.

8. The process of claim 1 wherein the aqueous chromium-free composition is free of added alkali metal ions.

9. The process of claim 1 further comprising depositing at least one additional layer over the treated layer of aluminum, wherein the additional layer comprises one or more of a metal layer or an organic coating.

10. The process of claim 1 wherein the hexafluorozirconate is provided as one or a mixture of any two or more of hexafluorozirconic acid, ammonium hexafluorozirconate, a quaternary ammonium hexafluorozirconate, an alkali metal hexafluorozirconate, an alkaline earth metal hexafluorozirconate, or a transition metal hexafluorozirconate.

11. A process for passivating a vapor-deposited aluminum layer on a substrate, comprising:
vapor depositing a layer of aluminum on a substrate;
treating the substrate with the vapor deposited aluminum with an aqueous substantially chromium-free composition comprising a hexafluorozirconate; and
rinsing the treated substrate with water.

12. The process of claim 11 wherein the chromium-free composition comprising a hexafluorozirconate further comprises a magnesium salt, a nickel salt, a zinc salt or a combination of any two or more of a magnesium salt, a nickel salt and a zinc salt.

13. The process of claim 11 wherein the vapor depositing is by decomposition of a metal-containing precursor having a decomposition temperature in a surrounding atmosphere, in which the substrate is maintained at a temperature greater than the decomposition temperature of the precursor while the surrounding atmosphere is maintained at a temperature lower than the decomposition temperature of the precursor.

14. The process of claim 11 wherein the vapor depositing is by one or a combination of two or more of chemical vapor deposition, ion vapor deposition and physical vapor deposition.

15. The process of claim 11 wherein the substrate comprises a ferrous metal.

16. The process of claim 15 wherein the ferrous metal is steel.

17. The process of claim 11 wherein the aqueous chromium-free composition is free of added zinc ions.

18. The process of claim 11 wherein the aqueous chromium-free composition is free of added alkali metal ions.

19. The process of claim 11 further comprising depositing at least one additional layer over the treated layer of aluminum, wherein the additional layer comprises one or more of a metal layer or an organic coating.

20. The process of claim 11 wherein the hexafluorozirconate is provided as one or a mixture of any two or more of hexafluorozirconic acid, ammonium hexafluorozirconate, a quaternary ammonium hexafluorozirconate, an alkali metal hexafluorozirconate, an alkaline earth metal hexafluorozirconate, or a transition metal hexafluorozirconate.
